(19) United States
(12) Patent Application Publication
(10) Pub. No.: US 2008/0176150 A1
(43) Pub. Date: Jul. 24, 2008

(54) Exposure mask and method of forming pattern

(76) Inventor: Masayoshi Saito, Tokyo (JP)

Correspondence Address: Paul J. Esatto, Jr.;Scully, Scott, Murphy & Presser, P.C., Suite 300, 400 Garden City Plaza, Garden City, NY, 11530, US

(21) Appl. No.: 12/009,309

(22) Filed: Jan. 17, 2008

(30) Foreign Application Priority Data
Jan. 22, 2007 (JP) 2007-011461

(51) Int. Cl. G03F 1/00; G03F 7/26

(52) U.S. Cl. 430/5; 430/311

(57) ABSTRACT

A method of forming a pattern according to the present invention comprising preparing a reduced projection exposure apparatus having a reduced projection ratio 1/m and a wavelength λ (nm) of exposing light and patterning a light shielding element pattern of a reticle mask on a resist film having a thickness tr (nm). The light shielding element pattern has a pattern opening portion having a minimum opening dimension D (nm). A thickness t0 of the light shielding element pattern is set so as to meet a relational equation of m*tr≦t0+5*D*D/λ. Preferably, the thickness t0 of the light shielding element pattern is set so as to meet a relational equation of m*tr≦t0+D*D/λ.

This application is based upon and claims the benefit of priority from Japanese patent application No. 2007-11461, filed on Jan. 22, 2007, the disclosure of which is incorporated herein in its entirety by reference.

### FIELD OF THE INVENTION

The present invention relates to improvement of a lithography process when manufacturing a semiconductor device and, in particular, to an exposure mask and a method of forming a pattern of the semiconductor device which are used for a fine dimension of a submicron region.

### BACKGROUND OF THE INVENTION

With the recent development of a manufacturing technology of a semiconductor device, a semiconductor device in which elements are integrated with high density has come into practical use. For example, in a Dynamic Random Access Memory, a memory having a storage capacity of 1 Gbit has come into practical use. With the high integration of the semiconductor device, an element pattern is to be miniaturized. Although a current minimum processing dimension is a submicron region, further miniaturization is considered for main purposes of cost reduction of an integrated circuit device and speed-up of an operating speed.

In a lithography process for manufacturing a semiconductor device, a reduced projection exposure apparatus (a stepper) is used. In the stepper, a pattern on an exposure mask (hereinafter, referred to as a “reticle mask”) is reduced and projected to a semiconductor substrate on a stage. When one shot exposure is terminated, the stage is moved in X and Y directions and next shot exposure is then carried out. By repeating such an operation, an overall surface of the semiconductor substrate is exposed. As an exposing light source, a light source of a short wavelength such as visible light (g-ray: wavelength of 436 nm), ultraviolet rays (i-ray: wavelength of 365 nm), a KrF laser (wavelength of 248 nm), and an ArF laser (wavelength of 193 nm) is used. There are various reticle masks that reduced projection ratio is in the range of 1/4to 1/10 or the like.

Exposure by a stepper will be described with reference to FIGS. 1A and 1B, and Table 1 (will be shown in the middle of this specification). FIG. 1A is a schematic view of exposure. FIG. 1B shows a reticle mask (left side) and an exposure pattern (right side). Table 1 shows a necessary thickness of a light shielding element in a reticle mask. A semiconductor substrate 6 is placed on a stage (not shown) that can be moved in X and Y directions. A film 7 to be processed is formed in the semiconductor substrate 6, and a resist film 8 is formed thereon. Exposing light from an exposing light source (not shown) enters a reticle mask 1. A light shielding element pattern 4 of the reticle mask 1 is reversed by a lens 5 to be projected in the resist film 8 on the semiconductor substrate 6. In the reticle mask 1, the light shielding element pattern 4 is formed on a reticle substrate 2. A thickness of the light shielding element pattern 4 is generally about 150 nm to 200 nm, and a thickness of the resist film 8 is about 500 nm to 1000 nm.

An element pattern is miniaturized with high integration of the semiconductor device, whereby a dimension of the light shielding element pattern 4 in the reticle mask 1 becomes smaller. Thus, in the case of a thickness of each of a light shielding element pattern and resist film according a related art, an image projected in the resist film includes a light shielding element and a Fresnel diffraction area in the vicinity of the light shielding element, and further includes a Fraunhofer diffraction area far from the light shielding element. As a result, as shown in FIG. 1A, a pattern (projection image) projected in the resist film 8 is fogged and widely deformed due to diffraction of the exposing light to be projected. In the case where the thickness of the light shielding element pattern 4 is relatively thinner than the thickness of the resist film 8 in this manner, there occurs a problem that the pattern (projection image) projected in the resist film 8 is fogged and widely deformed when the pattern is exposed. The film thickness of the light shielding element in the light shielding element pattern 4 of the reticle mask 1 is thinner than the necessary film thickness.

A representative example of the related art is shown in a column of the related art of Table 1. In the case where incident light wavelength λ is 248 nm and a minimum opening dimension D of the light shielding element pattern 4 in the reticle mask 1 is 90 nm, it meets D*D/λ=32.7 nm. The equation D*D/λ will be described later. In the case where the thickness of the resist film 8 is 480 nm and the reduced projection ratio is 1/4, a portion of 1920 nm in the area of the reticle mask 1 with respect to a traveling direction of the incident light is an area to be projected. However, as shown in Table 1, since the thickness of a representative light shielding element currently used is about 150 nm, the thickness of 150 nm of the light shielding element reaches less than 10% as long as the necessary dimension of 1920 nm. Even a value (314 nm) of the sum of the dimension of the light shielding element and the dimension of 5*D*D/λ=163.5 nm) reaches merely about 16% of the necessary dimension in the related art. Therefore, in the related art, not only a pattern image of the light shielding element is projected in the resist film, but also an image of the Fraunhofer diffraction area is projected.

The Fraunhofer diffraction area is an area in which a distance (a distance with respect to the traveling direction of the exposing light) Z from a bottom end surface of the light shielding element becomes D*D/λ<<Z. In this area, deformation of the light shielding element pattern and/or a sub peak becomes marked. As a concrete example, an example in which a resist pattern 12 is formed in a resist film 8 having a film thickness of 0.5 μm by means of ¼ reduced projection exposure to a rectangular hole pattern 11 is shown in FIG. 1B. An opening pattern by the light shielding element is a square 2 μm on a side. However, when a positive type resist film is exposed under standard conditions, a resist pattern 12 to be obtained has substantially a circular shape, and its diameter is smaller than 0.5 μm. Further, with respect to the formed resist pattern dimension, a diameter of the pattern of an isolated pattern area tends to become smaller than that in the area in which the pattern closes up.

As mentioned above, there is a problem that an image fogged and widely deformed from an original light shielding element pattern is projected in the resist film due to diffraction of the incident light. Further, since the film thickness of the light shielding element in the reticle mask is thinner, a projection image including an area in which diffraction of light passing through the opening pattern by the light shielding element occurs remarkably is formed in the resist film. As a result, there is a problem that a depth of focus (DOF) is small in view of a practical aspect. Moreover, the thickness of the resist film is set to be thicker in associated with processing of the film to be processed. Thus, there is a problem that the resist film is too thick compared with the film thickness of the light shielding element in the reticle mask and this causes low resolution. Furthermore, a technique to form the light shielding element by simply etching processing of a film made of chromium or the like with a resist mask has been adopted. Thus, there is also a problem that a yield on formation of the light shielding element pattern having a thick film thickness is lowered.

Following documents are related art documents relating to a lithography process of manufacturing a semiconductor device and a reticle mask. Patent Document 1 (Japanese Patent Application Publication No. 6-097029) discloses a pattern forming method in which a thickness of a light shielding element pattern in an oblique light incident exposure mask is made thicker, thereby obtaining a dimension near a design dimension. Further, an upper limit and a lower limit of the thickness of the light shielding element pattern are defined on the basis of an exposure wavelength λ, a numerical aperture NA, a projection exposure magnification (a reduced projection ratio) 1/m and a value a obtained by dividing a gap amount from the center of an opening diaphragm by a radius of the opening diaphragm. Patent Document 2 (Japanese Patent Application Publication No. 10-010703) discloses that a thickness of a light shielding element (chromium) pattern is set to a value in the proximity of n (where “n” is an integer number) times of ½ of an exposure wavelength to be used, thereby reducing an influence of comatic aberration of projection optics.

In Patent Document 3 (Japanese Patent Application Publication No. 2005-182031), in order to solve a problem to improve projection contrast, a thickness of a light shielding element in an exposure mask is set so as to be larger than a wavelength of exposing light, and so as to be less than three or four times as much as a width of the light shielding element pattern. As a principle to heighten contrast, by making the thickness of the light shielding element larger, an absorption ratio of TM polarization against TE polarization is increased, whereby the contrast is improved because interference of the TE polarization is increased at a semiconductor substrate level. The upper limit of the thickness of the light shielding element is set to three or four times as much as the width of the light shielding element pattern in accordance with intense shortness and cost of manufacture.

Patent Document 4 (Japanese Patent Application Publication No. 2005-50851), Patent Document 5 (Japanese Patent Application Publication No. 2004-4715), Patent Document 6 (Japanese Patent Application Publication No. 2004-77808), Patent Document 7 (Japanese Patent Application Publication No. 5-323563), and Patent Document 8 (Japanese Patent Application Publication No. 5-119464) respectively disclose that a light shielding element is achieved from one made of chromium oxide and having a thickness of 100 to 200 nm, one configured from a bilayer of chromium oxide and chromium and having a thickness of 50 to 120 nm, one configured from a bilayer structure of a chromium thin film having a thickness of 800 nm and a low-reflection chromium thin film having a thickness of 400 nm, one configured from a metal thin film layer having a thickness of 5 to 500 nm, and one configured from a light impermeable chromium film having a thickness of 50 to 300 nm. Although there are descriptions relating to a film thickness of a light shielding element of a mask in these Patent Documents, there is no explanation for a relationship to a resist film thickness. Therefore, there is no description about technical suggestion relating to the present invention.

### SUMMARY OF THE INVENTION

As described above, in the related art, in the case where the thickness of the light shielding element is smaller and the thickness of the resist film is larger, there is a problem that a pattern (a projection image) to be projected in the resist film is fogged and widely deformed due to diffraction of the exposing light (problem 1). A film thickness of the light shielding element pattern in the reticle mask is smaller, and a projection image including an area in which diffraction of the exposing light passing through an opening pattern by the light shielding element occurs remarkably is formed in the resist film. As a result, there is a problem that the depth of focus is smaller in view of the practical aspect (problem 2). Further, there is a problem that resolution is lowered because the thickness of the resist film is made larger in associated with processing of the film to be processed (problem 3).

The present invention aims to solve the problems described above by analyzing causes of pattern deformation on formation of an exposure pattern and taking a wave-optical approach.

More specifically, the present invention aims to provide a reticle mask suitable for a fine processing dimension and a pattern forming method for a semiconductor device.

According to a first aspect of the present invention, a method of forming a pattern is provided. The method comprises preparing a reduced projection exposure apparatus having a reduced projection ratio 1/m and a wavelength λ (nm) of exposing light and patterning a light shielding element pattern of a reticle mask on a resist film having a thickness tr (nm). The light shielding element pattern has a pattern opening portion having a minimum opening dimension D (nm). In this case, a thickness t0 of the light shielding element pattern is set so as to meet a relational equation of m*tr≦t0+5*D*D/λ.

In the first aspect, the thickness t0 of the light shielding element pattern may be set so as to meet a relational equation of m*tr≦t0+D*D/λ.

According to a second aspect of the present invention, a reticle mask is provided. The reticle mask is used in a reduced projection exposure apparatus having a reduced projection ratio 1/m and a wavelength λ (nm) of exposing light, and is used for patterning on a resist film having a thickness tr (nm). The reticle mask comprises a light shielding element pattern having a pattern opening portion with a minimum opening dimension D (nm). A thickness t0 of the light shielding element pattern is set so as to meet a relational equation of m*tr≦t0+5*D*D/λ.

According to a third aspect of the present invention, a method of manufacturing the reticle mask mentioned in the above second aspect is provided. The method comprises forming a groove in a reticle substrate, the groove having a depth t0 (nm), and embedding a light shielding element in the formed groove.

According to a fourth aspect of the present invention, a method of manufacturing a semiconductor device is provided. The method comprises patterning the resist film by means of the method of forming a pattern as mentioned the above first aspect and processing a film to be processed using the resist pattern formed by the patterning as a mask.

In the aspect of the present invention, a film thickness of a light shielding element pattern is made larger, and a resist film thickness is made smaller. Thus, processing of a fine pattern can be carried out without transcribing a spatial image of a Fraunhofer diffraction area into a resist film at the exposure. In the case of a reduced projection ratio of 1/m, a wavelength λ (nm) of exposing light, a minimum opening dimension D (nm) of a light shielding element pattern, a thickness t0 (nm) of the light shielding element pattern and a resist film thickness tr (nm), a fine pattern can be formed by setting m*tr≦t0+5*D*D/λ.

By making the thickness of the light shielding element pattern of the reticle mask lager, an effect to improve resolution of the resist pattern is achieved. Further, since high resolution is kept, an effect to make a depth of focus (DOF) lager is achieved. Moreover, when the light shielding element has a laminated structure, stress on the light shielding element can be reduced, whereby an effect to heighten a processing yield of the mask is achieved. In addition, an error caused by distortion due to stress at the pattern formation can be made smaller, whereby an effect to heighten pattern accuracy is achieved. Furthermore, by adopting a damascene structure for formation of the light shielding element, an effect that a light shielding element pattern having a high aspect ratio can be formed is achieved. A method of processing a film to be processed after transcribing a thin resist pattern into another layer has an effect that a relatively thick member can be processed with a high accuracy thin film resist pattern. Thus, a reticle mask suitable for fine processing and a pattern forming method of a semiconductor device can be obtained.

### BRIEF DESCRIPTION OF THE DRAWINGS

FIGS. 1A and 1B are respectively views for explaining an exposure in the related art and a view showing a reticle pattern and a resist pattern in the related art;

FIGS. 2A and 2B are respectively views for explaining diffraction of exposing light against a distance from a light shielding element pattern in a reticle mask and a view schematically showing an exposure form in order to explain a principle of the present invention;

FIG. 3 is a view schematically showing exposure in the related art;

FIG. 4 is a view schematically showing exposure in the embodiment of the present invention;

FIGS. 5A and 5B are sectional views respectively showing the case of exposure of a projection image formed inside a resist film in the related art and the case of exposure in the embodiment of the present invention;

FIGS. 6A and 6B are respectively a plan view and a sectional view of a scaling reticle mask;

FIGS. 6C and 6D are respectively a plan view and a sectional view of a normal reticle mask;

FIGS. 7A to 7F are respectively sectional views of multiple examples of the reticle mask;

FIG. 8A to 8C are respectively sectional views of multiple examples of the reticle mask having a damascene structure in which a light shielding element pattern of the reticle mask is embedded;

FIGS. 9A and 9B are respectively sectional views of two examples of the case where a light shielding element pattern is constructed from a main light shielding element pattern and an auxiliary light shielding element pattern;

FIGS. 10A to 10C are respectively sectional views of three examples of the case where a light shielding element pattern with a damascene structure is constructed from a main light shielding element pattern and an auxiliary light shielding element pattern;

FIGS. 11A and 11B are respectively a plan view and a sectional view of the case where the present invention is applied to a Levenson type phase shift reticle mask;

FIGS. 12A to 12D are respectively a plan view and sectional views of the case where the present invention is applied to a halftone type phase shift reticle mask;

FIGS. 13A to 13C are respectively sectional views for explaining a manufacturing flow of the reticle mask in the present invention in which a reduced projection ratio of an X direction is the same as that of a Y direction;

FIGS. 14A to 14C are respectively sectional views for explaining a manufacturing flow of a scaling reticle mask in the present invention;

FIGS. 15A to 15D are respectively sectional views for explaining a manufacturing flow of a reticle mask with a damascene structure in the present invention;

FIGS. 16A to 16F are respectively sectional views for explaining a manufacturing flow of a reticle mask with another damascene structure in the present invention;

FIGS. 17A to 17E are respectively sectional views for explaining a manufacturing flow of a reticle mask with still another damascene structure in the present invention;

FIGS. 18A to 18C are respectively sectional views for explaining a method of manufacturing a semiconductor device in the present invention in the case where a resist monolayer is used;

FIGS. 19A to 19C are respectively sectional views for explaining a method of manufacturing a semiconductor device in the present invention in the case where a resist and an intermediate mask layer are used;

FIGS. 20A to 20C are sectional views for explaining a method of manufacturing a semiconductor device in the present invention in the case where a multilayer resist is used; and

FIGS. 21A to 21E are respectively sectional views for explaining a method of manufacturing a semiconductor device in the present invention in which a CMP process, a resist and an intermediate mask layer are used.

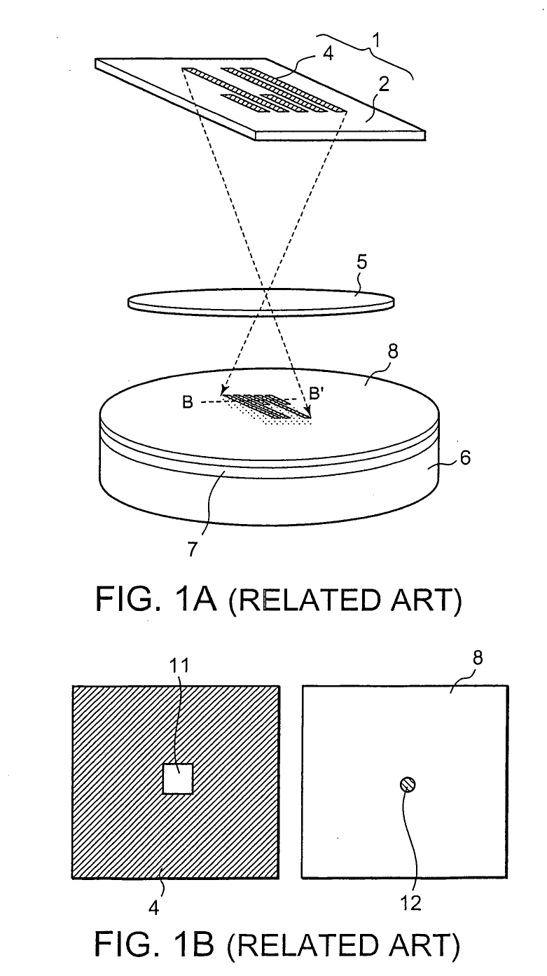

### DESCRIPTION OF THE EXEMPLARY EMBODIMENTS

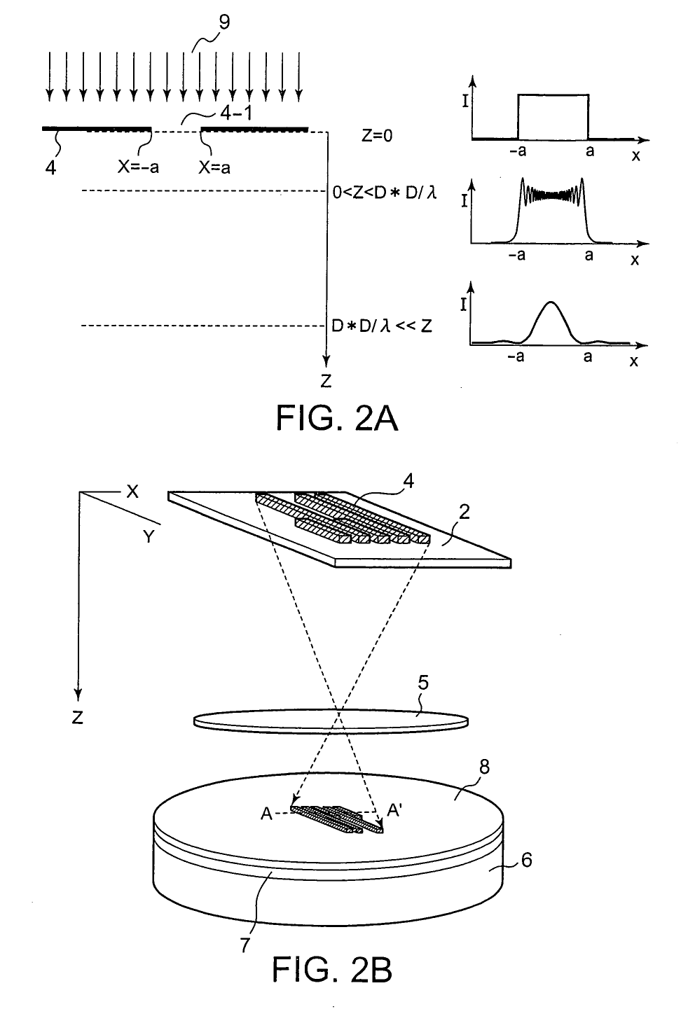

The present invention will be described with reference to FIGS. 2A and 2B. FIG. 2A is a view for explaining diffraction of exposing light against a distance from a light shielding element pattern. FIG. 2B schematically shows an exposure form.

The diffraction of exposing light relating to the present invention will be described with reference to FIG. 2A. Incident light 9 of FIG. 2A is light whose phase is uniform (visible light, ultraviolet rays, DUV (Deep UV) and the like). Although a thickness of a light shielding element pattern 4 is small, the light shielding element pattern 4 does not transmit the incident light 9, but transmits the incident light 9 only from an opening portion 4-1 (X=−a to X=a). A wavelength of the incident light 9 denotes λ and the minimum opening dimension of the light shielding element pattern 4 denotes D. A direction in which the incident light 9 travels denotes a Z axis and a distance from a light shielding element denotes Z. Namely, a bottom portion of the light shielding element is set to 0 as a reference point Z of the distance. Then, consider amplitude intensity I of the light at an area near the light shielding element, 0≦Z<D*D/λ, and an area far from it, D*D/λ<<Z. The amplitude intensity I of light corresponding to each of the areas is shown at upper right (Z=0), middle right (0<Z<D*D/λ), or lower right (D*D/λ<<Z) in FIG. 2A.

At the bottom surface of the light shielding element pattern 4 (Z=0), amplitude intensity of light becomes rectangular-shaped distribution as shown at the upper right of FIG. 2A because of a boundary condition physically applied. Further, the area near the light shielding element (0<Z<D*D/λ) is an area called a Fresnel diffraction area, and as shown at the middle right of FIG. 2A, distribution in which the rectangular shape becomes somewhat misshapen to oscillate is seen. However, in this area, by setting an image development threshold value of a resist film appropriately, a pattern substantially similar to the light shielding element pattern can be projected in the resist film. However, at the area far from the light shielding element (D*D/λ<<Z), as shown at the lower right of FIG. 2A, deformation due to diffraction becomes marked, and a sub peak and the like presents a problem. This area is called a Fraunhofer diffraction area, and is an area in which pattern deformation is caused.

Now, if the distance Z is 10*D*D/λ that is one digit larger than D*D/λ, it is said the area far from the light shielding element (D*D/λ<<Z). Here, with respect to the distance Z, consider the distance between the D*D/λ and the 10*D*D/λ. In the case where a paraxial approximation equation is discussed in view of whether or not a secondary term thereof can be omitted when a wave equation in which a light intensity distribution function is met is to be solved, it is to be said that the secondary term can be omitted so long as the Z is larger than the 10*D*D/λ. At the area in which the distance Z is smaller than the D*D/λ, it is necessary to leave the secondary term without being omitted. Thus, on the basis of the effect that an area at which diffraction occurs but deformation is small is admitted, in the present invention, Z=5*D*D/λ is considered to be a “near side boundary” at which inadmissible pattern deformation occurs. Moreover, more preferable distance Z is less than D*D/λ.

In the present invention, a thickness of a light shielding element of an exposure reticle mask is made larger, and a spatial image in a Fresnel diffraction area of light passing through an opening portion in the light shielding element is projected and exposed in the resist film formed on a surface of a semiconductor substrate. The spatial image at the distance Z more than about 5 times as far as the D*D*/λ at which the projection light is subjected to Fraunhofer diffraction is not to be projected in the resist film. A measure of the projected area is set to an area in which the thickness t0 of the light shielding element and a value of about 5 times as much as the D*D*/λ are added. It is further preferable to be an area in which the thickness t0 of the light shielding element and the D*D*/λ are added.

More specifically, the measure of the thickness t0 of the light shielding element is set so that a value m*tr obtained by multiplying a resist film thickness (tr) by a reciprocal number of a reduced projection ratio (1/m) is not greater than a value obtained by adding the thickness t0 of the light shielding element to the 5*D*D/λ. It is more preferable to be set so that the value m*tr is not greater than a value obtained by adding the thickness t0 of the light shielding element to the D*D/λ. Now, in the case where an application thickness of the resist film is 0.2 μm, a reduced projection ratio is 1/4, the wavelength λ of the incident light 9 is set to 248 nm, and the minimum opening dimension D of the light shielding element pattern 4 is set to 80 nm, then the thickness t0 of the light shielding element can be defined as follows.

m*tr≦t0+5*D*D/λ

4*0.2 μm≦t0+5*80 nm*80 nm/248 nm

671 nm≦t0

It is more preferable that the thickness t0 of the light shielding element is defined as follows.

m*tr≦t0+D*D/λ

4*0.2 μm≦t0+80 nm*80 nm/248 nm

774 nm≦t0

Further, in the case where the application thickness of the resist film is set to 0.1 μm, the thickness t0 of the light shielding element can be defined as follows.

4*0.1 μm≦t0+5*80 nm*80 nm/248 nm

271 nm≦t0

It is more preferable that the thickness t0 of the light shielding element is defined as follows.

4*0.1 μm≦t0+80 nm*80 nm/248 nm

374 nm≦t0

In addition, although the upper limit of the value of (t0+5*D*D/λ) depends to the respective values of the reduced projection ratio 1 μm, the wavelength λ, the thickness tr, and the minimum opening dimension D, it is desirable not greater than 1.0 μm.

Thus, an appropriate thickness of the light shielding element can be determined on the basis of the application thickness of the resist film, the reduced projection ratio, the wavelength of the incident light, and the minimum opening dimension of the light shielding element pattern. By carrying out reduced projection exposure using the reticle mask having the light shielding element pattern with the necessary thickness determined in this manner, the spatial image passing through the opening portion of the light shielding element and deformed due to the Fraunhofer diffraction can be prevented from being formed in the resist film. Namely, as shown in FIG. 2B, it is possible to form a pattern substantially similar to the light shielding element pattern 4 in the resist film 8. Therefore, the problem that the image fogged and widely deformed as explained above is projected in the resist film is solved. Moreover, even though the focus position is somewhat changed, the depth of focus (DOF) becomes larger, whereby it can be improved because the light shielding element has a necessary thickness. Further, since an adequate relationship between the thickness of the light shielding element and the thickness of the resist film is kept, a problem that resolution drops down can also be solved.

In the present invention, the appropriate thickness of the light shielding element is determined on the basis of the application thickness of the resist film, the reduced projection ratio, the wavelength of the incident light, and the minimum opening dimension of the light shielding element pattern. Compared with the related art, by making the application thickness of the resist film smaller and making the thickness of the light shielding element larger, Fraunhofer diffraction is prevent from occurring. As a result, a reticle mask capable of projecting a reticle pattern with a fine dimension of a submicron region in a resist film and a pattern forming method for a semiconductor device are provided.

### First Embodiment

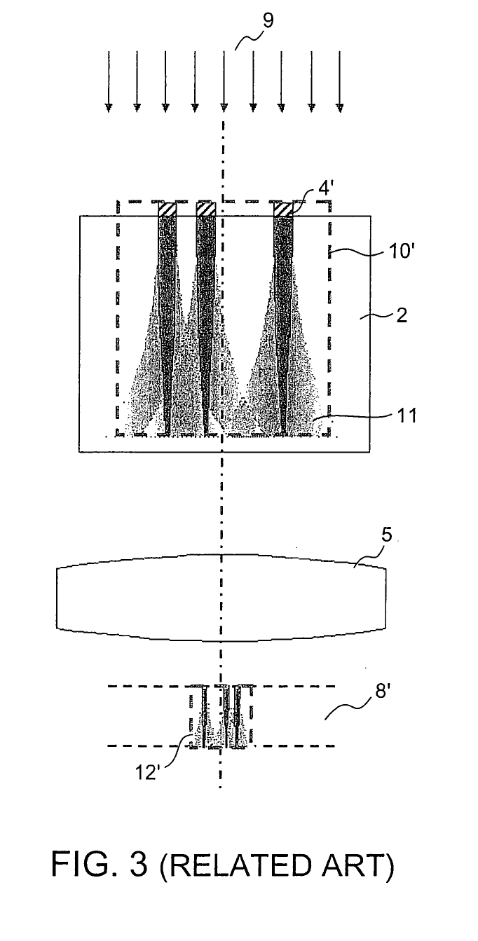

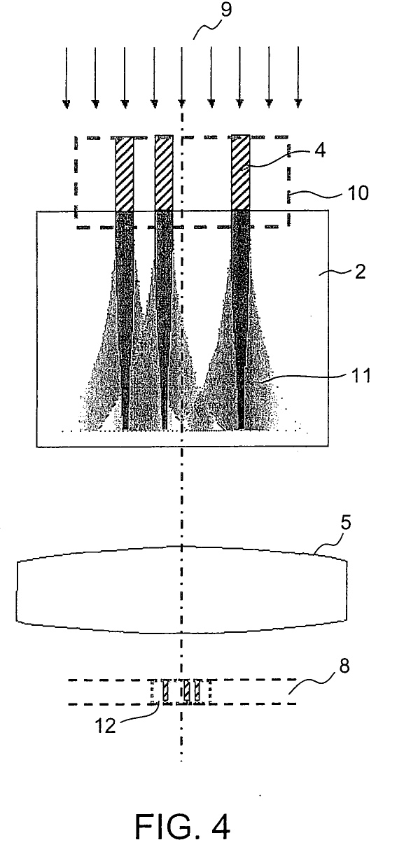

A first embodiment of the present invention will be described with reference to FIGS. 3 to 5. The first embodiment is an example of a pattern forming method. FIG. 3 schematically shows an exposure form in the related art. FIG. 4 schematically shows an exposure form in the present invention.

Although an illustration is omitted, a reticle mask and a semiconductor substrate are first prepared to be mounted on a stepper. In the reticle mask, a light shielding element pattern 4 (4′) is patterned on a reticle substrate 2. In the semiconductor substrate, a thin film to become a film to be processed is formed, and a resist film 8 (8′) having a predetermined thickness is formed on the film to be processed.

In FIG. 3 in which the related art is shown, the thickness of the light shielding element pattern 4′ is smaller, while the thickness of the resist film 8′ is larger.

On the other hand, in FIG. 4 in which the first embodiment of the present invention is shown, the thickness of the light shielding element pattern 4 is larger, while the thickness of the resist film 8 is smaller. By projecting a three-dimensional spatial image corresponding to the light shielding element pattern 4 of this reticle mask in the resist film 8, a reduced projection spatial image 12 is formed inside the resist film 8. In this case, the exposure apparatus may be a scan-and-repeat type one or a step-and-repeat type one. Further, a wavelength of a light source of the exposure apparatus is arbitrary, and a normal illumination method, a deformation illumination method or an oblique light illumination method may be used as an illumination method.

FIG. 3 is a view showing the related art in which the thickness of the light shielding element pattern 4′ is smaller and the thickness of the resist film 8′ is relatively larger. The incident light 9 (for example, KrF laser light having a wavelength λ of 248 nm) passing through an opening portion of the thin light shielding element pattern 4′ to be diffracted, and part thereof is bent to get into a shadow portion of the light shielding element pattern 4′. As a result, as it is separated from the light shielding element in the traveling direction of the incident light, the incident light causes Fresnel diffraction and Fraunhofer diffraction. When the thickness of the resist film 8′ is 0.4 μm and the reduced projection ratio is 1/4, a projected space 10′ (an area enclosed with a broken line in FIG. 3) becomes a wide area including transmission diffraction light 11 from an upper surface of the light shielding element pattern 4′.

In FIG. 3, the light shielding element pattern 4′ and the space 10′ of a transmission diffraction light area are projected in the resist film 8′ as a reduced projection spatial image 12′. The transmission diffraction light area is an area including a Fresnel diffraction area and a Fraunhofer diffraction area. In the spatial image of the Fraunhofer diffraction area, deformation becomes larger compared with that in the light shielding element pattern 4′, and the spatial image includes a sub peak component. Thus, the spatial image widely deformed is projected in the resist film 8′. Light propagating in a space is described with a wave equation, which can be subjected to Fourier transform. A lens 5 can be seen by causing the light of wave propagation with Fourier transform to be condensed at a focus and new Fourier transform is then added so as to spread.

Referring to FIG. 4, in the first embodiment of the present invention, the thickness of the light shielding element pattern 4 is made larger, while the thickness of the resist film 8 is made smaller to 0.15 μm. A projected space 10 becomes a narrow area constructed only from the light shielding element pattern 4 and the Fresnel diffraction area. As a result, a reduced projection spatial image 12 projected in the resist film 8 is obtained as a similar figure of the light shielding element pattern 4 that does not include the Fraunhofer diffraction area. Thus, since the Fraunhofer diffraction area is not projected in the resist film 8, deformation is smaller than that in the related art of FIG. 3, whereby it is possible to form a projection pattern closer to the similar figure of the light shielding element pattern 4.

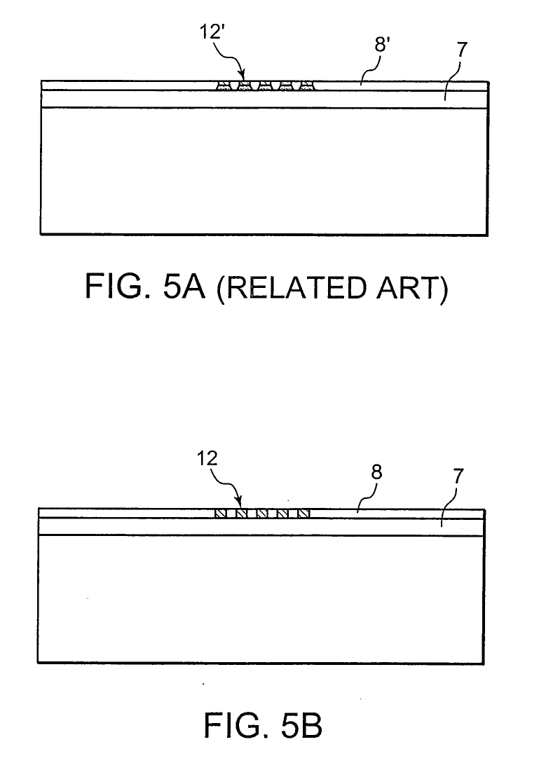

FIGS. 5A and 5B are sectional views for explaining an influence on a spatial image in which a thickness of a light shielding element pattern is formed in a resist film. FIG. 5A is the case of the related art in which a thin light shielding element pattern is used. In the vicinity of a surface of the resist film 8′, a sharp pattern corresponding to the light shielding element pattern is formed. However, since the resist film 8′ is thick, the Fraunhofer diffraction area is projected as it proceeds from a middle portion to a bottom portion of the resist film 8′. As a result, the reduced space projection image 12′ formed in the resist film 8′ does not become sharp but fogged.

On the other hand, in the case where the thickness of the light shielding element pattern is large as shown in FIG. 5B in the first embodiment of the present invention, a sharp projection image of the light shielding element pattern is projected in the resist film 8. Thus, a pattern having small deformation and a small sub peak can be formed. A high resolution is obtained by using above-mentioned light shielding elements. Moreover, it is effective that DOF can be enlarged.

In the following Table 1, distance setup condition dependence of the light shielding element thickness t0 is shown. A distance setup condition (1) is that the space 10 to be projected is not greater than the thickness t0 of the light shielding element pattern 4. A distance setup condition (2) is that the space 10 to be projected is not greater than the sum of the thickness to of the light shielding element pattern 4 and the D*D/λ. A distance setup condition (3) is that the space 10 to be projected is not greater than the sum of the thickness t0 of the light shielding element pattern 4 and the 5*D*D/λ. As a comparative example, values in the general related art are shown in a right column. In the related art, it can be seen that a setup distance is not met. Further, when the setup distance is spread up to t0+5*D*D/λ as the condition (3), it can be seen that an aspect ratio of the light shielding element is somewhat relieved.

TABLE 1
Distance Setup Condition Dependence of Thickness of Light Shielding
Element (t0)

| | | Condition | | |
|---|---|---|---|---|
| | Condition | (2) | Condition (3) | |
| | (1) | tr * m − D * | tr * m − 5D * | Related |
| Parameter | tr * m ≦ t0 | D/λ ≦ t0 | D/λ ≦ t0 | Art |
| Thickness of | 600 | 567 | 437 | 150 |
| Light Shielding | | | | |
| Element t0 (nm) | | | | |
| Aspect Ratio of | 6.7 | 6.3 | 4.9 | 1.7 |
| Light Shielding | | | | |
| Element | | | | |
| (A ratio) | | | | |
| Thickness of | 150 | 150 | 150 | 480 |
| Resist Film | | | | |
| t0 (nm) | | | | |
| Minimum | 90 | 90 | 90 | 90 |
| Opening | | | | |
| Dimension of | | | | |
| Light Shielding | | | | |
| Element D (nm) | | | | |
| Projection | 0.25 | 0.25 | 0.25 | 0.25 |
| Reduction Ratio | | | | |
| 1/m (ratio) | | | | |
| Wavelength of | 248 | 248 | 248 | 248 |
| Incident Light | | | | |
| λ (nm) | | | | |

Table 2 shows minimum opening dimension dependence in a distance setup condition (2), and shows the results in the case where the minimum opening dimension D in the distance setup condition (2) is changed into 90 nm, 70 mm, and 50 nm. As the opening dimension D becomes smaller due to a change in the D*D/λ, an aspect ratio (A ratio) becomes lager rapidly.

TABLE 2
Minimum Opening Dimension Dependence in Distance Setup
Condition (2)

| | Condition (2) | Condition (2) | Condition (2) |
|---|---|---|---|
| | D = 90 nm | D = 70 nm | D = 50 nm |
| | tr * m − D * | tr * m − D * | tr * m − D * |
| Parameter | D/λ ≦ t0 | D/λ ≦ t0 | D/λ ≦ t0 |
| Thickness of Light | 567 | 580 | 590 |
| Shielding Element | | | |
| t0 (nm) | | | |
| Aspect Ratio of Light | 6.3 | 8.3 | 11.8 |
| Shielding Element | | | |
| (A ratio) | | | |
| Thickness of Resist | 150 | 150 | 150 |
| Film | | | |
| t0 (nm) | | | |
| Minimum Opening | 90 | 70 | 50 |
| Dimension of Light | | | |
| Shielding Element | | | |
| D (nm) | | | |
| Projection Reduction | 0.25 | 0.25 | 0.25 |
| Ratio | | | |
| 1/m (ratio) | | | |
| Wavelength of | 248 | 248 | 248 |
| Incident Light | | | |
| λ (nm) | | | |

Table 3 shows resist film thickness dependence in a distance setup condition (2), and shows the result in the case where the resist film thickness tr in the distance setup condition (2) is changed into 150, 100, and 50 nm. It can be seen that as a resist film thickness is made smaller, an aspect ratio (A ratio) of the light shielding element is relieved rapidly. In the case where a resist film is thin, processing may become difficult when a monolayer resist pattern is masked thereon in view of a relationship between the film to be processed and a velocity ratio of dry etching (selectivity).

In such a case, a pattern forming method using an intermediate mask layer or multilayer resist (will be described later) allows an accurate pattern processing to be achieved.

TABLE 3
Resist Film Thickness Dependence in Distance Setup Condition (2)

| | Condition (2) | Condition (2) | Condition (2) |
|---|---|---|---|
| | tr = 150 nm | tr = 100 nm | tr = 50 nm |
| | tr * m − D * | tr * m − D * | tr * m − D * |
| Parameter | D/λ ≦ t0 | D/λ ≦ t0 | D/λ ≦ t0 |
| Thickness of Light | 580 | 380 | 180 |
| Shielding Element | | | |
| t0 (nm) | | | |
| Aspect Ratio of Light | 8.3 | 5.4 | 2.6 |
| Shielding Element | | | |
| (A ratio) | | | |
| Thickness of Resist | 150 | 100 | 50 |
| Film | | | |
| t0 (nm) | | | |
| Minimum Opening | 70 | 70 | 70 |
| Dimension of Light | | | |
| Shielding Element | | | |
| D (nm) | | | |
| Projection Reduction | 0.25 | 0.25 | 0.25 |
| Ratio | | | |
| 1/m (ratio) | | | |
| Wavelength of | 248 | 248 | 248 |
| Incident Light | | | |
| λ (nm) | | | |

In the first embodiment, an optimum thickness of the light shielding element is determined on the basis of the application thickness of the resist film, the reduced projection ratio, the wavelength of the incident light, and the minimum opening dimension of the light shielding element pattern. By making the application thickness of the resist film thinner and making the thickness of the light shielding element thicker compared with the related art, a spatial image of the area in which Fraunhofer diffraction does not occur is projected in the resist film. Thus, a reticle pattern with a fine dimension of a submicron region can be projected in the resist film suitably. In the case of the reduced projection ratio of 1/m, the wavelength λ of the incident light, the minimum opening dimension D of the light shielding element pattern, the thickness t0 of the light shielding element pattern and the resist film thickness tr, it is set to m*tr≦t0+5*D*D/λ. By setting it in this manner, a pattern forming method of a semiconductor device by which the reticle pattern with a fine dimension of a submicron region can be projected in the resist film suitably can be obtained.

### Second Embodiment

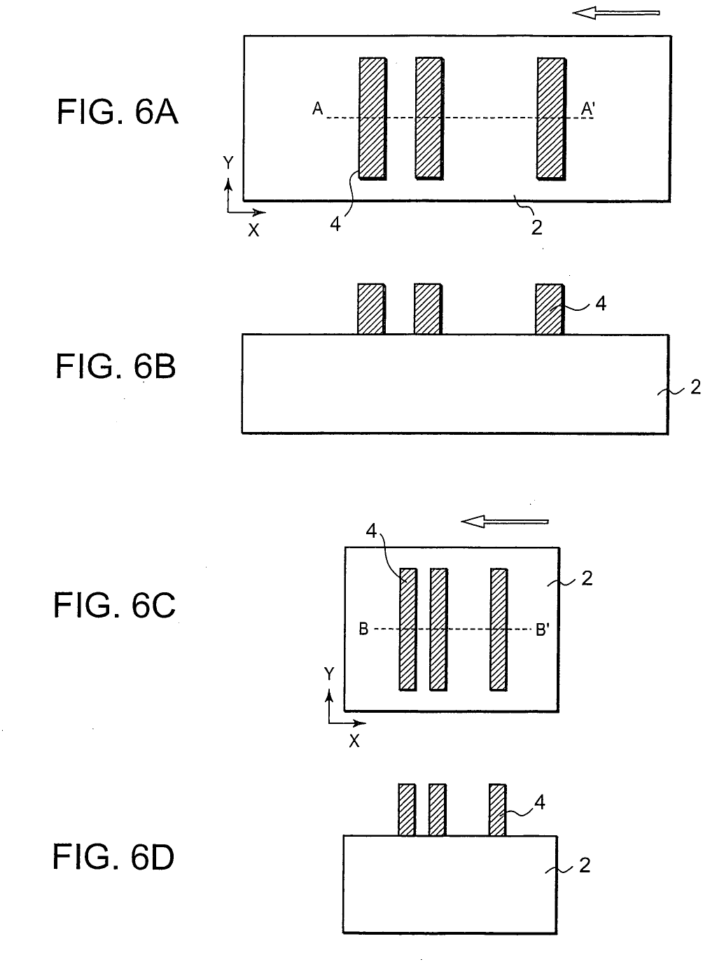

A second embodiment of the present invention will be described with reference to FIGS. 6A to 6D. In the second embodiment, a thickness of a light shielding element pattern of a reticle mask is made larger, while the aspect ratio becomes larger. The second embodiment is an example in which the present invention is applied to the reticle mask used in the present invention. FIG. 6A is a plan view of a scaling reticle mask. FIG. 6B is a sectional view taken along the line A-A′ of FIG. 6A. FIG. 6C shows a plan view of the reticle mask (normal reticle mask) used in the related art. FIG. 6D shows a sectional view taken along the line B-B′ of FIG. 6C.

In an exposure reticle mask, a light shielding element pattern 4 is formed on a reticle substrate 2. In the second embodiment, “m” denotes a reciprocal number of a reduced projection ratio, “tr” denotes a thickness of a resist film, “t0” denotes a thickness of a light shielding element pattern, “D” denotes a minimum opening dimension of the light shielding element pattern, and “λ” denotes a wavelength of incident light. A measure of a thickness t0 of the light shielding element pattern 4 is set so as to meet the following equation (condition 3).

m*tr≦t0+5*D*D/λ

It is more preferable that it is set so as to meet the following equation (condition 2).

m*tr≦t0+D*D/λ

It is further more preferable that it is set so as to meet the following equation (condition 1).

m*tr≦t0

In order to meet the above conditions, a ratio (an aspect ratio) of the thickness to a bottom portion dimension of light shielding element becomes larger as shown in Table 1. Even in the case where the condition 3 in which the aspect ratio becomes smaller is applied, the aspect ratio of the light shielding element pattern becomes 4.9, and an advanced technology is required for processing of the reticle mask. As means for relieving the aspect ratio, a scaling reticle mask can be utilized.

In the scaling reticle mask shown in FIGS. 6A and 6B, a pattern is in advance caused to extend in a scanning direction (X direction indicated by an arrow in FIGS. 6A and 6B) in a scanning exposure system, a reticle mask having a room by the amount to be extended is transmitted at scanning exposure. Extension of the pattern is set to twice as much as the normal reticle mask, for example. In this case, the thickness of the light shielding element remains the same without change, while each of the width and space thereof becomes twice. Thus, the aspect ratio is reduced down to half. The decrease of the aspect ratio by half enables to facilitate processing of the reticle mask. Both reduction ratios of the normal reticle mask in the X and Y directions shown in FIGS. 6C and 6D are the same magnification, and the aspect ratio thereof becomes larger. However, needless to say, it can be used in the present invention.

In the present invention, either a normal reticle mask in which reduced projection ratios in the X and Y directions are the same as each other or a scaling reticle mask in which reduced projection ratios in the X and Y directions are different from each other can be used. In the case where a scaling reticle mask is used, an aspect ratio can be made smaller. Thus, an advantage that workability thereof can be improved and it is thus easy to manufacture it can be achieved. By using these reticle masks, a pattern forming method of a semiconductor device by which a fine dimension pattern of a submicron region can be projected in the resist film suitably can be obtained.

### Third Embodiment

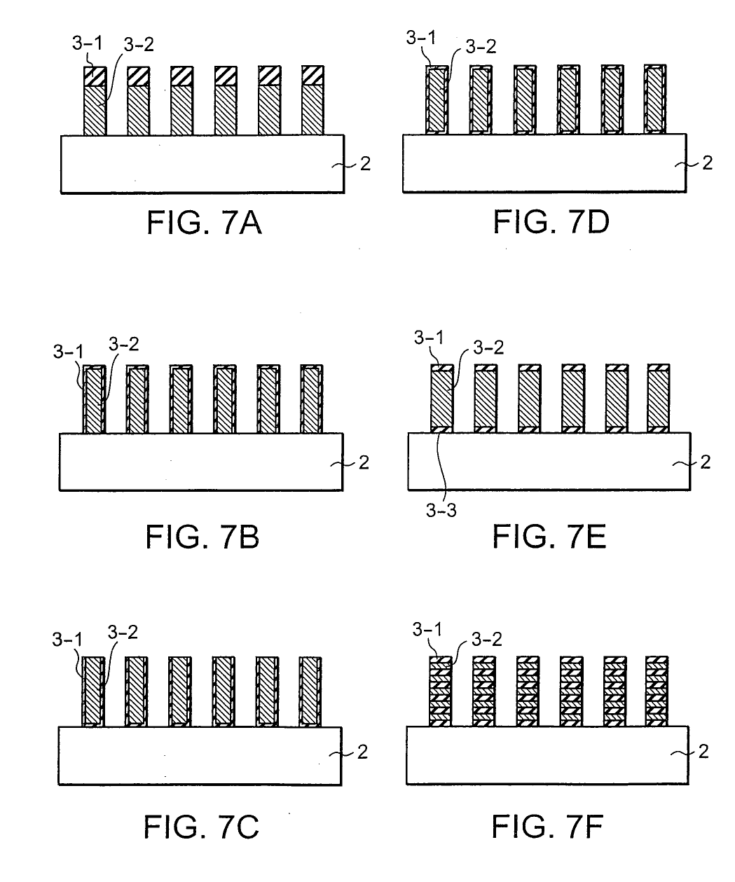

A third embodiment of the present invention will be described with reference to FIGS. 7A to 7F through FIGS. 12A to 12D. In the third embodiment, the thickness of the light shielding element pattern of the reticle mask becomes larger and the aspect ratio becomes larger. Therefore, the third embodiment is an example in which a configuration of the light shielding element pattern in the reticle mask is improved.

The light shielding element of the reticle mask can be constructed from a single member as explained with reference to FIGS. 6A to 6D. However, the light shielding element is not limited to this, and it can be constructed from a plurality of light shielding layers.

FIGS. 7A to 7F respectively show sections of various reticle masks constructed from a plurality of light shielding layer. The total thickness of the plurality of light shielding layers is set so as to become the thickness t0 that meets the conditional equations described above. The light shielding element pattern of FIG. 7A is a bilayer laminated structure, and is constructed from a first light shielding layer 3-1 of an upper layer and a second light shielding layer 3-2 of a lower layer. The light shielding element pattern of FIG. 7B has a structure in which an upper surface and a side surface of the second light shielding layer 3-2 are covered with the first light shielding layer 3-1.

The light shielding element pattern of FIG. 7C has a structure in which a bottom surface and a side surface of the second light shielding layer 3-2 are covered with the first light shielding layer 3-1. The light shielding element pattern of FIG. 7D has a structure in which all of an upper surface, a bottom surface and a side surface of the second light shielding layer 3-2 are covered with the first light shielding layer 3-1.

The light shielding element pattern of FIG. 7E is a trilayer laminated structure, and is constructed from a first light shielding layer 3-1 of an upper layer, a second light shielding layer 3-2 of an intermediate layer and a third light shielding layer 3-3 of a lower layer. By further laminating a plurality of laminated films each constructed from the first light shielding layer 3-1 and the second light shielding layer 3-2, the light shielding element pattern may has a multilayer laminated structure as the light shielding element pattern of FIG. 7F. This example is suitable for controlling distortion due to stress so as to become smaller.

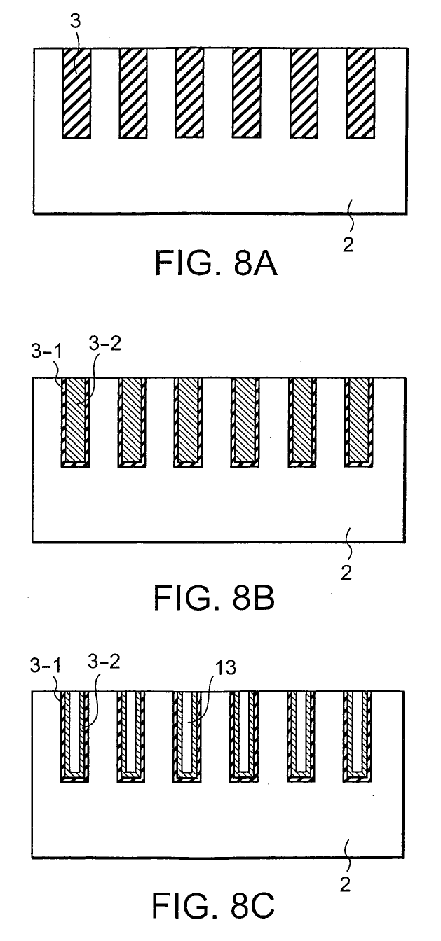

FIGS. 8A to 8C respectively show sections of various reticle masks of a damascene structure in which a light shielding element is embedded inside a reticle substrate. FIG. 8A is a damascene structure in which a light shielding element pattern is formed by embedding a light shielding element 3 of a single member in a groove of a reticle substrate 2. Further, as shown in FIG. 8B, two kinds of light shielding layers 3-1, 3-2 may be embedded in the groove of the reticle substrate 2. In the case where a glue layer is used at the embedding process, it becomes a structure as in FIG. 8B. Moreover, as shown in FIG. 8C, it can have a structure in which the light shielding layers 3-1, 3-2 and an embedded member 13 are embedded in the groove of the reticle substrate 2. Furthermore, a reticle mask having a structure in which a groove is left in place of the embedded member 13 in FIG. 8C can be used. Namely, in the case where a light shielding layer is disposed on a sidewall and a bottom surface of the groove, it prevents incident light from transmitting. Thus, the inside of the light shielding layer 3-2 is never subjected to restrictions.

Since the aspect ratio of the light shielding element pattern is large in this manner, the light shielding element pattern has a damascene structure in which the light shielding element pattern is embedded in the reticle substrate. In the case of the damascene structure, a depth of the groove to be embedded is set so as to be the thickness t0 that meets the above conditional equations. By setting the depth of the groove to be t0, a height in a vertical direction perpendicular to a surface of the reticle substrate becomes to, thereby preventing diffraction of the incident light. Here, a structure in which a light shielding element pattern is formed in a reticle substrate surface is called a coplanar structure. In the case of the coplanar structure, the thickness of the light shielding element pattern is set to the t0. In the case of the damascene structure, the depth of the groove in the light shielding element is set to the t0. Both the thickness of the light shielding element in the coplanar structure and the depth of the groove in the damascene structure achieve the same function to prevent incident light from transmitting. Therefore, the thickness of the light shielding element and the depth of the groove can be simplified to be simply defined as the thickness of the light shielding element and the height of the light shielding element pattern, respectively. Light shielding elements with high aspect ratio can be formed using a multi-layered structure and/or the damascene structure. Therefore, there is an effect to improve the resolution and the accuracy in patterning.

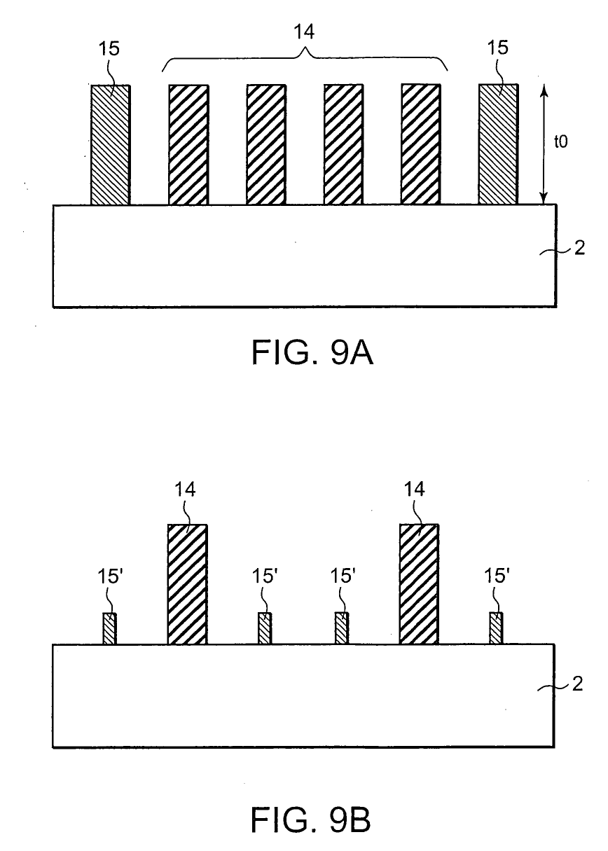

FIGS. 9A and 9B show another structure of the reticle mask in the present invention, and show sections of various reticle masks in which an auxiliary light shielding element pattern is arranged in addition to the main light shielding element pattern.

In an example of FIG. 9A, an auxiliary light shielding element pattern 15 is arranged on the reticle substrate 2 in addition to the main light shielding element pattern 14. In the present example, thicknesses of the main light shielding element pattern 14 and the auxiliary light shielding element pattern 15 are the same as the thickness t0. In the case where a layout area has to spare in this manner, it is preferable to arrange the auxiliary light shielding element pattern 15 that can be resolved. The auxiliary light shielding element pattern 15 that can be resolved has substantially the same size as the adjacent main light shielding element pattern 14, and is called a dummy pattern. The auxiliary light shielding element pattern 15 that can be resolved is arranged around the periphery of a semiconductor device, for example, and is used as a dummy for accurately patterning of the inner main light shielding element pattern 14.

However, in the case where there is no space on the reticle substrate 2 to arrange the auxiliary light shielding element pattern 15 that can be resolved, an auxiliary light shielding element pattern 15′ that is not resolved is arranged as shown in FIG. 9B. The auxiliary light shielding element pattern that is not resolved is a pattern used for a purpose of an OPC (Optical Proximity Correction), and is actually not resolved because the size thereof is less than a resolution limit. As shown in FIG. 9B, when the thickness of the auxiliary light shielding element pattern 15′ is made smaller than the thickness t0 of the main light shielding element pattern 14, it is possible to cause it not to be resolved surely, whereby a manufacturing yield of the reticle mask can also be improved. Thus, a technique that the OPC auxiliary light shielding element pattern 15′ that is not resolved is arranged around the main light shielding element pattern 14 to carry out proximity correction can be adopted in the reticle mask of the present invention.

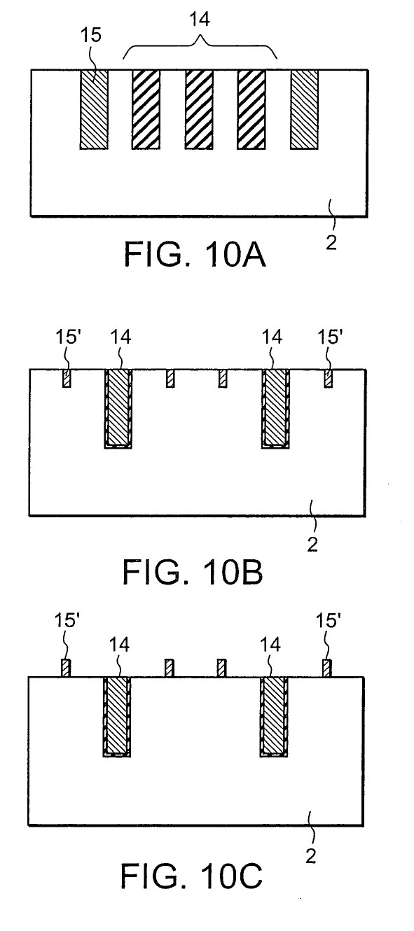

FIGS. 10A, 10B and 10C show still another structure of the reticle mask in the present invention, and show sections of various reticle masks in which a main light shielding element pattern of a damascene structure and an auxiliary light shielding element pattern are embedded in the reticle substrate 2. FIG. 10A is the case where there is a room for a layout area of the reticle substrate 2, and an auxiliary light shielding element pattern 15 that can be resolved and having a groove depth t0 the same as that of a main light shielding element pattern 14 is embedded. However, in the case where there is no room to arrange the auxiliary light shielding element pattern 15 that can be resolved, an auxiliary light shielding element pattern 15′ that is not resolved is embedded as shown in FIG. 10B. The auxiliary light shielding element pattern 15′ is to be embedded so that the depth of the groove thereof is made smaller than that of the main light shielding element pattern 14.

Further, the auxiliary light shielding element pattern 15′ that is not resolved may be formed so as not to have a damascene structure but a coplanar structure in which it protrudes upward on the reticle substrate 2 as shown in FIG. 10C. In this case, a thin light shielding element layer for an auxiliary light shielding element pattern is formed after embedding the main light shielding element pattern 14, and the auxiliary light shielding element pattern is then formed using a resist pattern. In this regard, although the main light shielding element pattern 14 is a bilayer in FIGS. 10B and 10C, it is not particularly limited. For example, it may be an embedded film as a monolayer. Further, it may be constructed from a plurality of light shielding layers. The damascene structure and the coplanar structure can exist together in this manner.

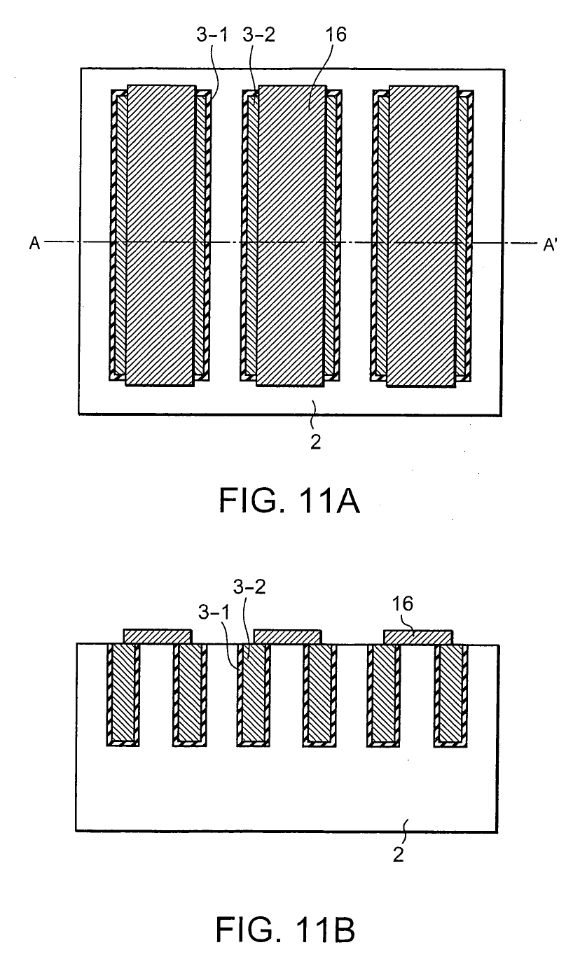

FIGS. 11A and 11B are a plan view and a sectional view of a Levenson type phase shift reticle mask, respectively. Even though light shielding layers 3-1, 3-2 of a damascene type are arranged in the Levenson type phase shift pattern 16 in combination with each other, a Levenson type phase shift mask can be formed without a problem. The Levenson type phase shift pattern 16 is arranged so that the positions of end portions of the light shielding layers 3-1, 3-2 of the damascene type are differentiated. By differentiating the positions of the end portions of the light shielding layers 3-1, 3-2, a phase of the light is changed (or shifted).

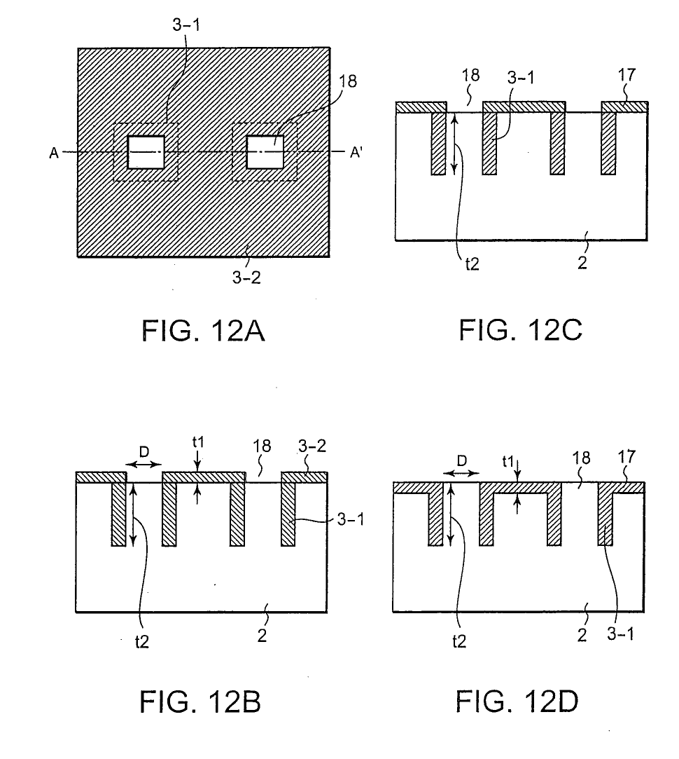

FIG. 12A is a plan view of a halftone type phase shift reticle mask. FIGS. 12B to 12D are sectional views taken along the line A-A′ of FIG. 12A. A light shielding layer 3-2 having opening portions 18 is formed on a surface of a reticle substrate 2, and a light shielding layer 3-1 is embedded in the reticle substrate 2 so as to enclose an outer edge of each of the opening portions 18. Thus, a section of the reticle mask can be configured as in FIG. 12B. A groove is formed in the reticle substrate 2 so as to be in contact with a periphery of each of the opening portions 18, and the light shielding layer 3-1 is embedded therein. Further, the thin light shielding layer 3-2 is formed on the surface of the reticle substrate 2 at a predetermined area other than the opening portions 18. Here, the sum of a thickness t1 of the light shielding layer 3-2 and a thickness t2 of the light shielding layer 3-1 is set to be the same as the thickness t0 described above.

Alternatively, as shown in FIG. 12C, a halftone phase shift pattern 17 may be arranged in place of the upper light shielding layer 3-2. Each of the light shielding layer 3-2 and the halftone phase shift pattern 17 has a coplanar structure in which it is formed on the surface of the reticle substrate 2. However, as shown in FIG. 12D, the surface of the reticle substrate 2 and the upper surface of the light shielding layer may be configured so as to be substantially the same height as each other. In this case, the thickness t2 of the light shielding layer 3-1 is set so as to be the same as the thickness t0 described above.

In the present invention, by making the thickness of the light shielding element pattern of the reticle mask larger, the aspect ratio thereof becomes larger. Thus, a monolayer or a plurality of light shielding layers may be laminated as the light shielding element pattern. Further, a groove is provided in the reticle substrate, whereby it may be a damascene structure in which the light shielding layer is embedded in the groove. Moreover, an auxiliary light shielding element pattern for correction may be provided. Furthermore, it may be a Levenson type phase shift mask or a halftone type phase shift mask. By using these reticle masks provided with the light shielding element pattern, a pattern forming method of a semiconductor device by which the reticle pattern with a fine dimension of a submicron region can be projected in the resist film suitably can be obtained.

### Fourth Embodiment

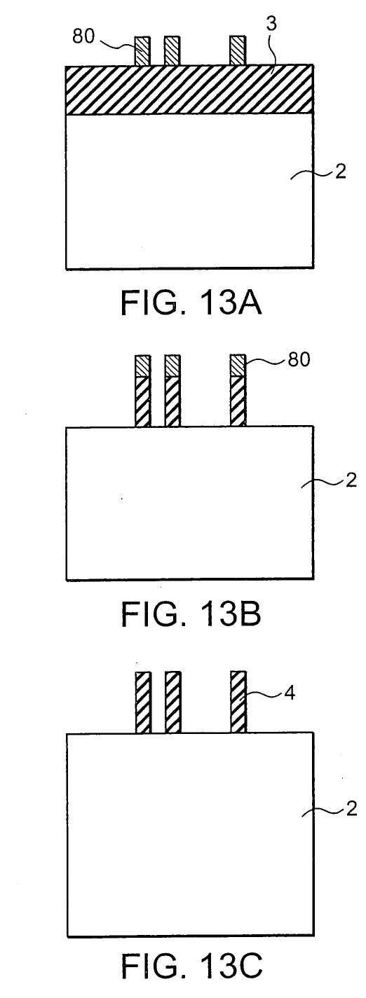

A fourth embodiment of the present invention will be described with reference to FIGS. 13A to 13C through FIGS. 17A to 17E. The fourth embodiment relates to a method of manufacturing a reticle mask provided with a light shielding element pattern having a large aspect ratio.

FIGS. 13A to 13C show, using sectional views, a manufacturing flow of a reticle mask in which a reduced projection ratio in the X direction is the same as that in the Y direction.

In FIG. 13A, a light shielding element 3 is formed on a reticle substrate 2 having high permeability by means of a sputtering method or the like, and a resist film 80 is patterned on the light shielding element 3 by means of electron beam drawing. The light shielding element 3 is subjected to dry etching using the resist film 80 as a mask (FIG. 13B) to form a light shielding element pattern 4 (FIG. 13C). Chromium, chromium oxide or the like is commonly used as the light shielding element 3, and in the related art, a thickness thereof is generally about 50 to 200 nm. A thickness of the light shielding element 3 in the present invention is set to a thick film thickness t0 as described above.

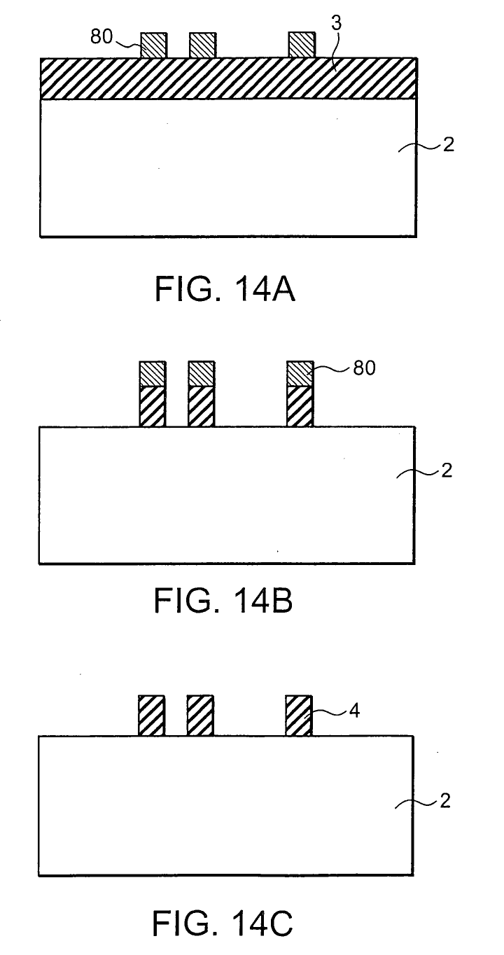

FIGS. 14A to 14C show a manufacturing flow of a scaling reticle mask with sectional views. By extending a pattern in a scanning direction, an aspect ratio is relieved, whereby a reticle mask processing yield is improved. In the case where an extension ratio is twice, the aspect ratio is relieved to 1/2. A manufacturing method of a scaling reticle mask will be described. In the similar manner to that described above, a light shielding element 3 with a film thickness t0 is formed on the reticle substrate 2 with high permeability by means of a sputtering method or the like, and a resist film 80 is patterned on the light shielding element 3 by means of electron beam drawing (FIG. 14A). The light shielding element 3 is subjected to dry etching using this resist pattern as a mask (FIG. 14B) to form a light shielding element pattern 4 (FIG. 14C).

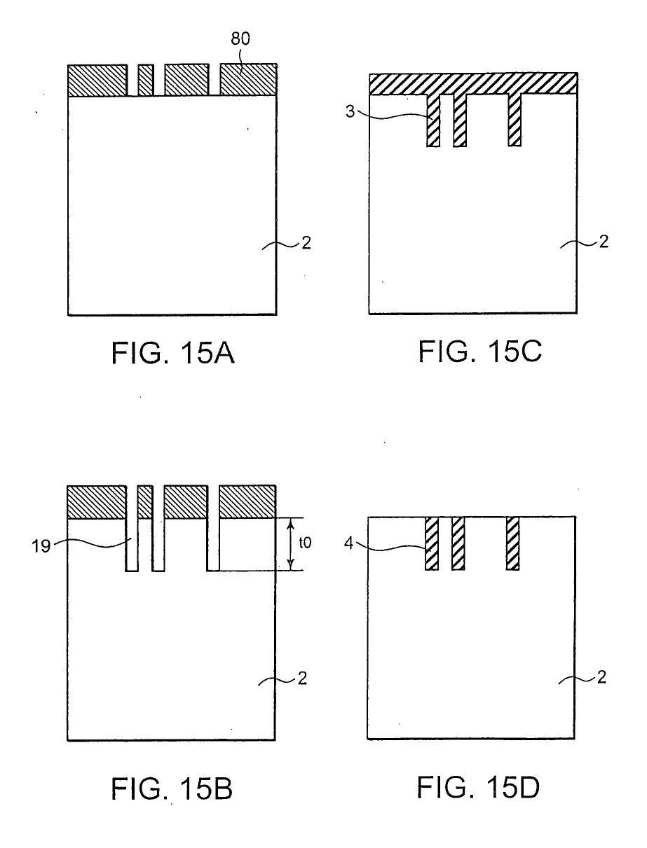

FIGS. 15A to 15D show a manufacturing flow of a reticle mask with a damascene type structure with sectional views. A resist pattern is formed after forming a resist film 80 on a reticle substrate 2 with high permeability (FIG. 15A). Anisotropic etching is carried out by applying a dry etching method, and a groove 19 with a depth t0 is formed in the reticle substrate 2 (FIG. 15B). Next, the resist film 80 is removed, and a light shielding element 3 is then embedded in the groove 19 (FIG. 15C). The light shielding element 3 may have small permeability against exposing light, and is formed by embedding metal or metal oxide by means of a sputtering method or a plating method. The light shielding element other than a portion where it is embedded in the groove 19 is removed by means of CMP (Chemical Mechanical Polishing) and the like (FIG. 15D). The light shielding element other than the portion where it is embedded in the groove 19 may be removed by means of an etchback method by applying dry etching.

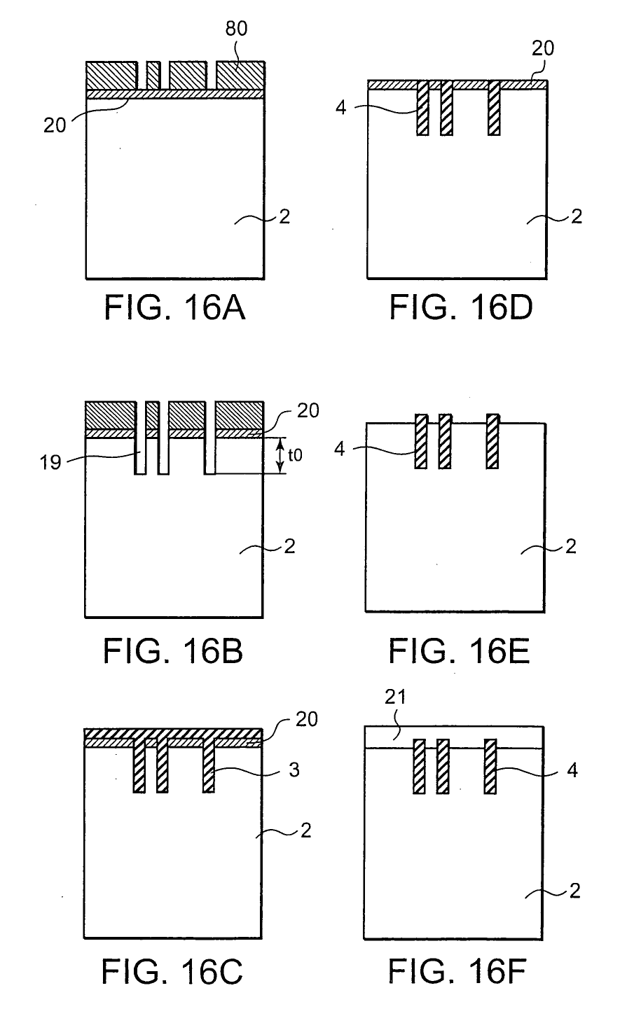

FIGS. 16A to 16F show an alternative example of the manufacturing method explained using FIGS. 15A to 15D. A resist film 80 is formed after forming an intermediate film 20 on a reticle substrate 2 to form a resist pattern by means of patterning (FIG. 16A). Anisotropic etching is carried out by applying a dry etching method to form a groove 19 with a depth t0 in the reticle substrate 2 (FIG. 16B). Next, the resist film 80 is removed, and a light shielding element 3 is embedded in the groove 19 (FIG. 16C). The light shielding element 3 other than a portion where it is embedded in the groove 19 is removed by means of CMP, whereby a light shielding element pattern 4 is formed (FIG. 16D).

The intermediate film 20 is a member having a property that it can be removed from the reticle substrate 2 with selectivity. By using such an intermediate film 20, even though a scratch occurs in the CMP, this influence can be removed. When the intermediate film 20 is removed after the CMP, as shown in FIG. 16E, a part of the light shielding element pattern 4 protrudes from the surface of the reticle substrate 2. A cap member 21 with high permeability is formed so as to embed this protruding portion (FIG. 16F).

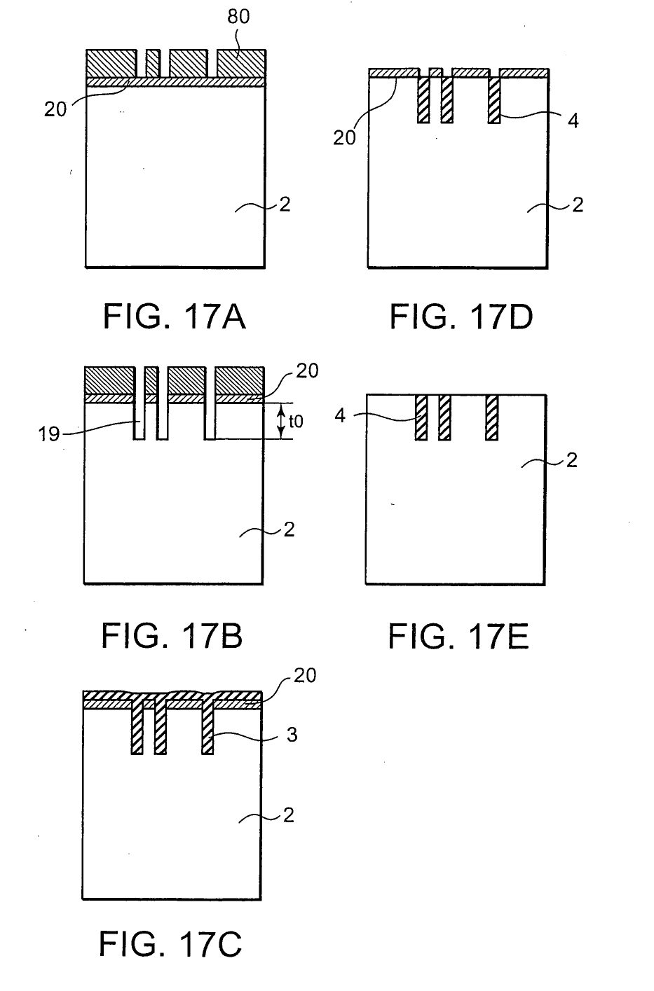

FIGS. 17A to 17E are an alternative example of the manufacturing method explained using FIGS. 16A to 16F. A resist film 80 is formed after forming an intermediate film 20 on a reticle substrate 2, and a resist pattern is formed by means of patterning (FIG. 17A). Anisotropic etching is carried out by applying a dry etching method to form a groove 19 in the reticle substrate 2 (FIG. 17B). A depth of the groove 19 is set to t0 as a depth inside the reticle substrate 2. Next, the resist film 80 is removed, and a light shielding element 3 is embedded in the groove 19 by means of a coating method (FIG. 17C). In the embedding of the light shielding element 3, a liquid in which a solvent containing metal to become the light shielding element 3 is dissolved, or a liquid containing fine particles such as metal or its oxide may be embedded in the groove 19 by means of spin coating, and it may then be baked to extract the solvent.

When a portion of the light shielding element 3 other than the groove 19 is removed by means of dry etching, a film thickness of the intermediate film 20 is over etched to form a light shielding element pattern 4 (FIG. 17D). By carrying out the over etching, the surface of the reticle substrate 2 and the upper end surface of the light shielding element pattern 4 can be aligned when the intermediate film 20 is removed (FIG. 17E). In the case where such a manufacturing method is used, it can be applied even though an aspect ratio of the light shielding element pattern 4 becomes relatively large.

The film thickness of the light shielding element pattern of the reticle mask in the present invention is larger, and the aspect ratio is larger. Such a reticle mask can be made using the various manufacturing methods described above. By using the reticle mask made using these manufacturing methods, a pattern forming method of a semiconductor device by which the reticle pattern with a fine dimension of a submicron region can be projected in the resist film suitably can be obtained. Light shielding elements with high aspect ratio can be formed in the damascene structure without a collapse. Therefore, a fabrication yield of reticle mask is improved, and there is an effect of decreasing the manufacturing cost, too.

### Fifth Embodiment

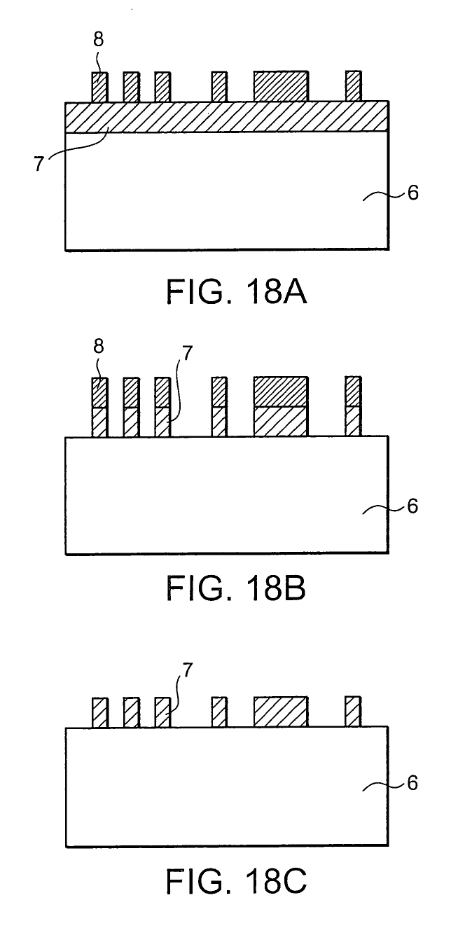

A fifth embodiment of the present invention will be described with reference to FIGS. 18A to 18C through FIGS. 21A to 21E. The fifth embodiment relates to a method of manufacturing a semiconductor device, and has a feature in a patterning method in which a film to be processed is subjected to etching by means of a resist pattern formed by projection exposure of a light shielding element pattern of a reticle mask.

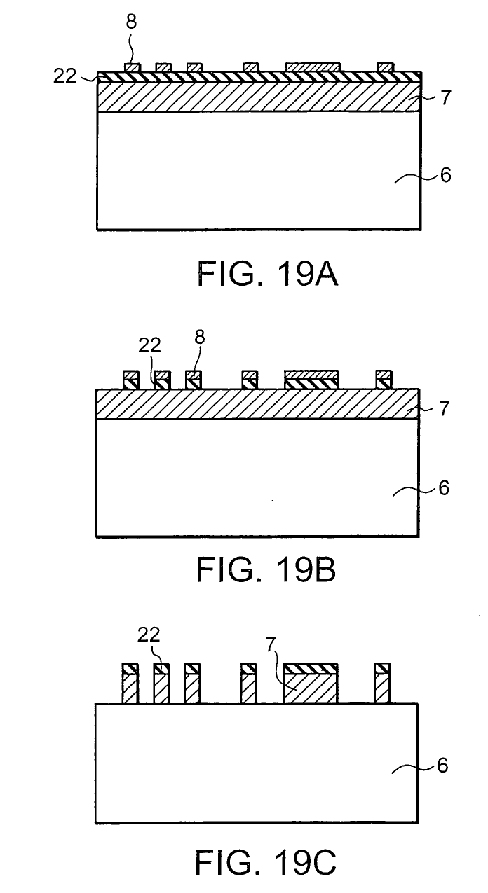

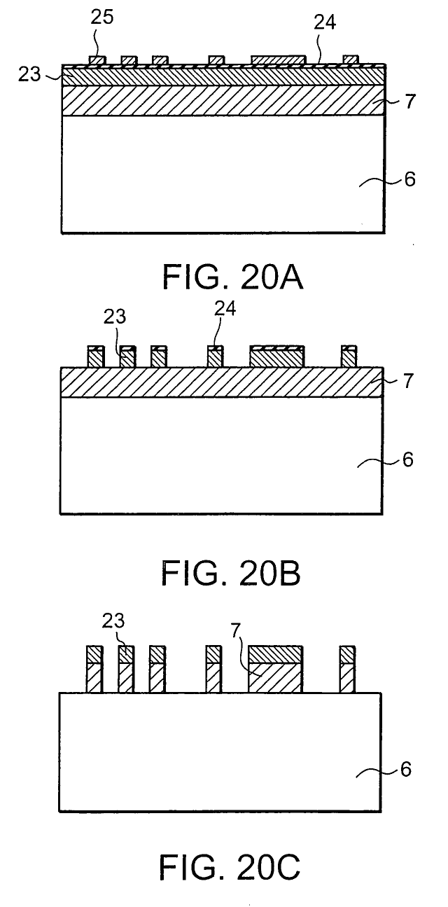

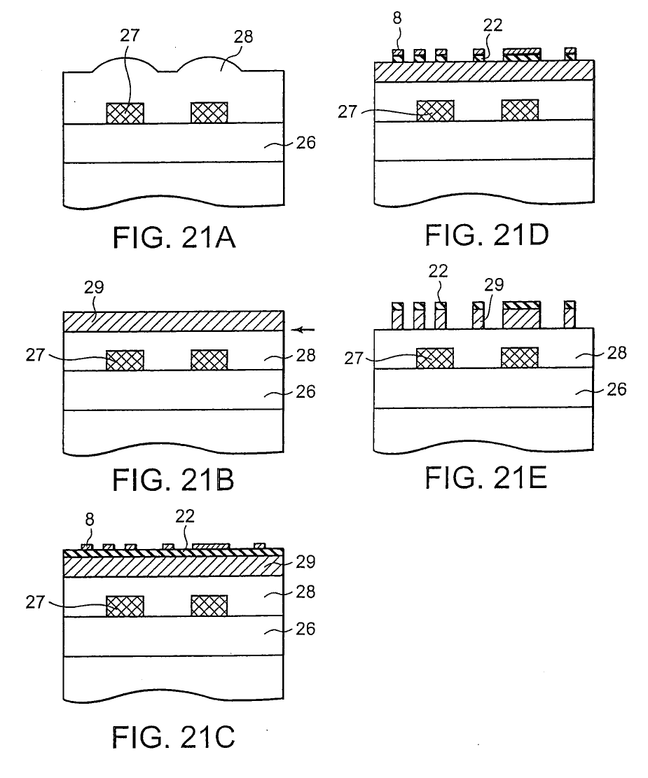

FIGS. 18A to 18C are sectional views for explaining a patterning method in which a resist monolayer is used. FIGS. 19A to 19C are sectional views for explaining a patterning method in which a resist and an intermediate mask layer are used. FIGS. 20A to 20C are sectional views for explaining a patterning method in which a multilayer resist is used. FIGS. 21A to 21E are sectional views for explaining a patterning method in which a surface of a semiconductor substrate is planarized and a resist and an intermediate mask layer are used. An appropriate method can be selected on the basis of a film to be processed thickness, a resist film thickness and an etching selection ratio from the methods of manufacturing shown in FIGS. 18A to 18C through FIGS. 21A to 21E.

A semiconductor substrate on which a reticle mask, a film to be processed and a resist film are formed is prepared to be placed in an exposure apparatus (a stepper). A three-dimensional spatial image corresponding to the light shielding element pattern of the reticle mask is formed in the resist film, whereby a resist pattern is formed. Patterning is made by subjecting the film 7 to be processed to etching using this resist pattern. In this case, the stepper may be a scan-and-repeat type one or a step-and-repeat type one. However, the scan-and-repeat type stepper is suitable when the scaling reticle mask is used. Further, a wavelength of a stepper light source is arbitrary. Moreover, a normal illumination method, a deformation illumination method or an oblique light illumination method may be used as an illumination method.

A patterning method using a resist monolayer will be described with reference to FIGS. 18A to 18C. A film 7 to be processed is formed on a semiconductor substrate 6, and a resist film 8 formed on the film 7 to be processed is subjected to patterning (FIG. 18A). The film 7 to be processed is subjected to etching using the resist pattern formed by the patterning as a mask (FIG. 18B). The resist pattern is then removed, whereby the patterning process for the film 7 to be processed is completed (FIG. 18C). This patterning method uses a resist monolayer, and it is applied in the case where an etching selection ratio between the resist film 8 and the film 7 to be processed is large. Since the etching selection ratio between the resist film 8 and the film 7 to be processed is not ensured, the following method is applied in the case where the film thickness of the resist film 8 disappears at the etching of the film 7 to be processed.

A patterning method using a resist film and an intermediate mask layer will be described with reference to FIGS. 19A to 19C. In the case where the etching selection ratio between the resist film and the film to be processed is not ensured, an intermediate mask layer is disposed, and processing can be carried out. A film 7 to be processed and an intermediate mask layer 22 are formed on a semiconductor substrate 6, a resist film 8 formed on the intermediate mask layer 22 is subjected to patterning (FIG. 19A). The intermediate mask layer 22 is subjected to etching using the resist pattern formed by the patterning as a mask (FIG. 19B). Further, the resist pattern is removed, and the film 7 to be processed is subjected to etching using the intermediate mask layer 22 as a mask, whereby the patterning process for the film 7 to be processed is completed (FIG. 19C). Here, the intermediate mask layer 22 may be removed, or may not be removed.

One in which the etching selection ratio to the film 7 to be processed can be ensured is selected as the intermediate mask layer 22. For example, in the case where the film 7 to be processed is a silicon film, a silicon oxide film is suitable for the intermediate mask layer 22. In the case where the film 7 to be processed is a silicon oxide film, a polycrystalline silicon film is suitable for the intermediate mask layer 22. In the case where the etching selection ratio between the resist film 8 and the film 7 to be processed cannot be ensured in this manner, a light shielding element pattern is transcribed on the resist film 8, and the intermediate mask layer 22 is subjected to etching. Then, the film 7 to be processed can be subjected to etching using the intermediate mask layer 22 as a mask.

The film thickness of the resist film 8 is determined on the basis of an etching rate ratio (selection ratio) to the film 7 to be processed, and a sharp image corresponding to the light shielding element of the reticle mask is formed in this resist film 8 as a resist pattern. The film 7 to be processed is processed by means of etching using the resist pattern as a mask. Further, in the case where the thickness of the resist film 8 cannot be set to be thicker against the film 7 to be processed, a suitable intermediate mask layer 22 is disposed between the resist film 8 and the film 7 to be processed. After the resist pattern is projected on the intermediate mask layer 22, the film 7 to be processed is processed using the pattern of the intermediate mask layer 22. By causing the intermediate mask layer 22 to intervene in this manner, an adequate relationship between the thickness of the light shielding element pattern and the thickness of the resist film 8 is kept. Thus, a pattern having good resolution can be obtained.

A patterning method using a multilayer resist will be described with reference to FIGS. 20A to 20C. As shown in FIG. 20A, a base resin layer 23, an intermediate inorganic layer 24 and an upper photosensitivity resist layer 25 are in order formed as a multilayer resist on a film 7 to be processed formed on a semiconductor substrate 6. Subsequently, a resist pattern is formed on the upper photosensitivity resist layer 25. This resist pattern is transcribed in the intermediate inorganic layer 24 using a dry etching method. Next, the base resin layer 23 is processed. In this case, the upper photosensitivity resist layer 25 is removed by means of the etching at the same time (FIG. 20B). Subsequently, the film 7 to be processed is subjected to dry etching. By causing the intermediate inorganic layer 24 to have an appropriate film thickness, the intermediate inorganic layer 24 is etched and removed at the dry etching at the same time, and it becomes a structure as shown in FIG. 20C. Since only the base resin layer 23 exists on the film 7 to be processed, a sharp film to be processed can be patterned by removing this by means of ashing.

A method of planarizing a surface of a semiconductor substrate and carrying out patterning using a resist and an intermediate mask layer will be described with reference to FIGS. 21A to 21E. This patterning method is a method of planarizing a surface of a semiconductor substrate when concavity and convexity of a base are large, then forming and processing a film to be processed. In the present invention, a thin resist film of about 0.1 μm may be used. In such a case, when the concavity and convexity of the base is large, it may be difficult to form a resist film having a flat surface. In this case, for example, by applying the CMP thereto to planarize it, it is possible to process an extremely fine pattern.

As shown in FIG. 21A, a first wiring 27 and a second insulation film 28 are formed on a first insulation film 26. In this case, the first wiring 27 causes the surface of the second insulation film 28 to make the concavity and convexity thereof larger. After the surface of the second insulation film 28 is planarized by means of the CMP, a wiring film to become a second wiring 29 is formed on the second insulation film 28 (FIG. 21B). Further, an intermediate mask layer 22 and a resist film 8 are formed on the wiring films to subject the resist film 8 to patterning (FIG. 21C). The intermediate mask layer 22 is subjected to etching using a resist pattern formed by means of patterning as a mask (FIG. 21D). Moreover, the resist pattern is removed, whereby the second wiring 29 is subjected to etching processing using the intermediate mask layer 22 as a mask (FIG. 21E).

In the method of manufacturing the semiconductor device according to the fifth embodiment, the film thickness of the light shielding element pattern is made larger, and the resist film thickness is made smaller. Thus, a method of manufacturing a semiconductor device by which processing of a fine pattern can be carried out can be obtained without transcribing a spatial image in a Fraunhofer diffraction area at the exposure into a resist film. In the method of manufacturing the semiconductor device, in the case where the resist film is thinner and an etching selection ratio cannot be ensured, it is possible to ensure the etching selection ratio by adopting the intermediate mask layer, the multilayer resist and the CMP. Thus, a method of manufacturing a semiconductor device by which a pattern with a fine dimension of a submicron region can be processed can be obtained.

In the present invention, the film thickness of the light shielding element pattern is made larger, and the resist film thickness is made smaller. Thus, the processing of a fine pattern can be carried out without transcribing the spatial image in the Fraunhofer diffraction area at the exposure to the resist. A reticle mask in which reduced projection ratios in the X and Y directions are the same magnification or a scaling reticle mask can be used as a reticle mask. The light shielding element pattern may have a damascene structure, or an auxiliary pattern may be combined therewith. The present invention can also be applied to a Levenson type phase mask and a halftone type phase mask.

In the method of manufacturing the semiconductor device according to the present invention, since the resist film is thin, the intermediate mask layer, the multilayer resist and the CMP may be adopted in the case where the etching selection ratio cannot be ensured. Thus, it is possible to ensure the etching selection ratio.

As described above, according to the present invention, a reticle mask suitable for fine processing and a pattern forming method of a semiconductor device can be obtained.

As explained above, although the present invention has specifically been described in conjunction with the plurality of embodiments thereof, the present invention is not limited to the embodiments described above, but various modifications may be applied to the present invention without departing from the scope and spirit of the present invention. Needless to say, such variations are to be included within the present invention.

What is claimed is:

1. A method of forming a pattern, the method comprising:
preparing a reduced projection exposure apparatus having a reduced projection ratio 1/m and a wavelength λ (nm) of exposing light; and
patterning a light shielding element pattern of a reticle mask on a resist film having a thickness tr (nm),
wherein the light shielding element pattern has a pattern opening portion having a minimum opening dimension D (nm), and
wherein a thickness t0 of the light shielding element pattern is set so as to meet a relational equation of m*tr≦t0+5*D*D/λ.

2. The method according to claim 1, wherein the thickness t0 of the light shielding element pattern is set so as to meet a relational equation of m*tr≦t0+D*D/λ.

3. The method according to claim 1, wherein the reticle mask is a scaling reticle mask extended in a scanning direction.

4. The method according to claim 1, wherein the value of (t0+5*D*D/λ) is not greater than 1.0 μm.

5. A reticle mask used in a reduced projection exposure apparatus having a reduced projection ratio 1/m and a wavelength λ (nm) of exposing light, and used for patterning on a resist film having a thickness tr (nm), the reticle mask comprising:
a light shielding element pattern having a pattern opening portion with a minimum opening dimension D (nm),
wherein a thickness t0 of the light shielding element pattern is set so as to meet a relational equation of m*tr≦t0+5*D*D/λ.

6. The reticle mask according to claim 4, wherein the light shielding element pattern comprises a plurality of light shielding layers.

7. The reticle mask according to claim 5, wherein the light shielding element pattern is a damascene structure in which a light shielding layer is embedded in a reticle substrate, and an embedded depth of the light shielding layer is the same as the thickness t0 (nm) of the light shielding element pattern.

8. The reticle mask according to claim 7, further comprising a Levenson type phase shift pattern.

9. The reticle mask according to claim 5, wherein the light shielding element pattern includes a main light shielding element pattern and an auxiliary light shielding element pattern disposed adjacent to the main light shielding element pattern.

10. The reticle mask according to claim 9, wherein a thickness of the auxiliary light shielding element pattern is smaller than a thickness of the main light shielding element pattern.

11. The reticle mask according to claim 5, wherein the light shielding element pattern positioned at an outer edge of the pattern opening portion is a damascene structure in which a light shielding element is embedded in a reticle substrate to a depth t0 (nm), the light shielding element pattern positioned at other area than the pattern opening portion is a coplanar structure with a thickness t1 (nm), and the thickness t0 is more than the thickness t1.

12. The reticle mask according to claim 11, wherein the light shielding element pattern positioned at other area than the pattern opening portion is a halftone phase shift pattern.

13. A method of manufacturing the reticle mask as claimed in claim 5, the method comprising:
forming a groove in a reticle substrate, the groove having a depth to (nm); and
embedding a light shielding element in the formed groove.

14. The method according to claim 13, wherein the embedding the light shielding element includes applying application liquid containing a component of the light shielding element to form a thin film and then baking the thin film.

15. The method according to claim 13, wherein the embedding the light shielding element includes planarizing with a CMP method or an etchback method.

16. A method of manufacturing the reticle mask as claimed in claim 10, the method comprising:
processing the main light shielding element pattern; and
processing the auxiliary light shielding element pattern,
wherein the thickness of the auxiliary light shielding element pattern is made smaller than the thickness of the main light shielding element pattern.

17. A method of manufacturing the reticle mask as claimed in claim 11, the method comprising:
forming a light shielding element pattern positioned at an outer edge of the pattern opening portion, the light shielding element pattern being a damascene structure; and
forming a light shielding element pattern, the light shielding element pattern being a coplanar structure.

18. A method of manufacturing a semiconductor device, the method comprising:
patterning the resist film by means of the method of forming a pattern as claimed in claim 1; and
processing a film to be processed using the resist pattern formed by the patterning as a mask.

19. The method according to claim 18, further comprising:
forming an intermediate mask layer; and
patterning the formed intermediate mask layer by means of the resist pattern,
wherein the film to be processed is processed using the patterned intermediate mask layer as a mask.

20. The method according to claim 18, wherein the resist film is a multilayer resist.

21. The method according to claim 18, further comprising:
planarizing a surface of the semiconductor substrate before forming the resist film.
